(19) United States
(12) Patent Application Publication
(10) Pub. No.: US 2013/0011987 A1
(43) Pub. Date: Jan. 10, 2013

(54) METHOD FOR FABRICATING SEMICONDUCTOR DEVICE WITH VERTICAL GATE

(76) Inventor: Jung-Hee PARK, Gyeonggi-do (KR)

(21) Appl. No.: 13/295,354

(22) Filed: Nov. 14, 2011

(30) Foreign Application Priority Data
Jul. 5, 2011 (KR) 10-2011-0066511

(51) Int. Cl. H01L 21/02; H01L 21/28

(52) U.S. Cl. 438/381; 438/585; 257/E21.19; 257/E21.008

(57) ABSTRACT

A method for fabricating a semiconductor device includes forming a plurality of pillars by etching a semiconductor substrate, forming a conductive layer over a semiconductor substrate structure including the pillars, forming preliminary gates on sidewalls of each pillar by performing a first etch process on the conductive layer, and forming vertical gates by performing a second etch process on upper portions of the preliminary gates.

### CROSS-REFERENCE TO RELATED APPLICATIONS

The present application claims priority of Korean Patent Application No. 10-2011-0066511, filed on Jul. 5, 2011, which is incorporated herein by reference in its entirety.

### BACKGROUND

1. Field

Exemplary embodiments of the present invention relate to a method for fabricating a semiconductor device, and more particularly, to a method for fabricating a semiconductor device with vertical gates.

2. Description of the Related Art

Pattern shrinkage may be one of essential factors in the yield of semiconductor devices. Masks used to fabricate the semiconductor devices get smaller and smaller for the pattern shrinkage thereof. Furthermore, an argon fluoride (ArF) photoresist (PR) layer have been developed for semiconductor devices of 40 nm or less. However, as the patterns of the semiconductor devices get even smaller, use of the ArF photoresist layer are reaching physical limits in patterning the semiconductor devices.

Therefore, patterning technologies are being developed for semiconductor devices, such as Dynamic Random Access Memory (DRAM), and three-dimensional (3D) cells are being formed therein.

Transistors having planar channels have reached physical limits with respect to leakage current, on-current, and short channel effect due to the miniaturization of a semiconductor device. Therefore, transistors using vertical channels, which are referred to as vertical channel transistors hereafter, are being developed.

A vertical channel transistor includes a pillar-shaped active region vertically stretching from a semiconductor substrate, a gate electrode formed on the sidewall of the pillar-shaped active region, which is referred to as a vertical gate VG, and a junction area formed in the upper and lower portions of the pillar-shaped active region around the vertical gate VG.

FIGS. 1A and 1B are cross-sectional views illustrating a conventional method for forming vertical gates of a semiconductor device.

Referring to FIG. 1A, a plurality of pillars 13 that are isolated from each other by trenches 12 are formed over a semiconductor substrate 11. The pillars 13 are active regions. The pillars 13 are formed using a hard mask layer 14 as an etch barrier.

A gate insulation layer 15 is formed over the pillars 13 and the hard mask layer 14, and then a conductive layer 16 is formed over the gate insulation layer 15 to gap-fill the spaces between the pillars 13, i.e., the trenches 12.

Referring to FIG. 1B, a portion of the conductive layer 16 is recessed, and then the conductive layer 16 is etched using a photoresist layer pattern 17. As a result, vertical gates 16A are formed on the sidewalls of the pillars 13.

According to the conventional technology which is described above, the vertical gates 16A are formed by forming the conductive layer 16 to gap-fill the space between the pillars 13 and then etching the conductive layer 16 by using the photoresist layer pattern 17. In short, the vertical gates 16A are formed through a method of etching the central portion of the gap-filled conductive layer 16 and the separate vertical gates 16A are formed on each side of the pillars 13.

According to the conventional technology, however, the vertical gates 16A may not have the same thickness and even each vertical gate 16A may not have the uniform thickness at the upper and lower portions. Moreover, the silicon at the bottom of the trenches 12 may be irregularly lost (18) during a separation etching process due to the slight difference between the spaces, and to make it worse, the gap-filled conductive layer 16 may not be separated.

Also, although the 20 nm-wide conductive layer 16 is to be formed and separated for a semiconductor device of 30 nm or less, an etch method using the photoresist layer pattern 17 may not separate such conductive layer 16.

### SUMMARY

Exemplary embodiments of the present invention are directed to a method for fabricating a semiconductor device that may have separate vertical gates even in a narrow space between pillars.

In accordance with an exemplary embodiment of the present invention, a method for fabricating a semiconductor device includes: forming a plurality of pillars by etching a semiconductor substrate; forming a conductive layer over a semiconductor substrate structure including the pillars; forming preliminary gates on sidewalls of each pillar by performing a first etch process on the conductive layer; and forming vertical gates by performing a second etch process on upper portions of the preliminary gates.

In accordance with another exemplary embodiment of the present invention, a method of fabricating a semiconductor device includes forming a plurality of pillars by etching a semiconductor substrate, forming a conductive layer over a semiconductor substrate structure including the pillars, and forming vertical gates by etching the conductive layer through an etch process performed in a direction perpendicular to the semiconductor substrate.

In accordance with yet exemplary another embodiment of the present invention, a method of fabricating a semiconductor device may include forming a plurality of bodies that are isolated from each other by a plurality of first trenches by etching a semiconductor substrate, forming buried bit lines that are coupled with the respective bodies at a portion of one sidewall thereof by partially filling the first trenches, forming a plurality of pillars that are isolated from each other by a plurality of second trenches crossing the first trenches by etching the upper portion of each body, forming a conductive layer over a semiconductor substrate structure including the pillars, forming preliminary gates on sidewalls of each pillar by performing a first etch process on the conductive layer, and forming vertical gates by performing a second etch process on the upper portions of the preliminary gates.

### BRIEF DESCRIPTION OF THE DRAWINGS

FIGS. 1A and 1B are cross-sectional views illustrating a conventional method for forming vertical gates of a semiconductor device.

FIGS. 2A to 2F are cross-sectional views illustrating a method for forming vertical gates of a semiconductor device in accordance with a first exemplary embodiment of the present invention.

FIGS. 3A to 3F are cross-sectional views illustrating a method for forming vertical gates of a semiconductor device in accordance with a second exemplary embodiment of the present invention.

FIGS. 4A and 4B are cross-sectional views illustrating a method for forming vertical gates of a semiconductor device in accordance with a third exemplary embodiment of the present invention.

FIGS. 5A and 5B are cross-sectional views illustrating a semiconductor device fabricated through a vertical gate forming method in accordance with an exemplary embodiment of the present invention.

FIGS. 6A to 6M are cross-sectional views illustrating the vertical gate forming method until the formation of buried bit lines (i.e., before the formation of vertical gates), which is shown in FIG. 5A.

FIGS. 7A to 7H are cross-sectional views illustrating the vertical gate forming method after the formation of buried bit lines, which is shown in FIG. 5B.

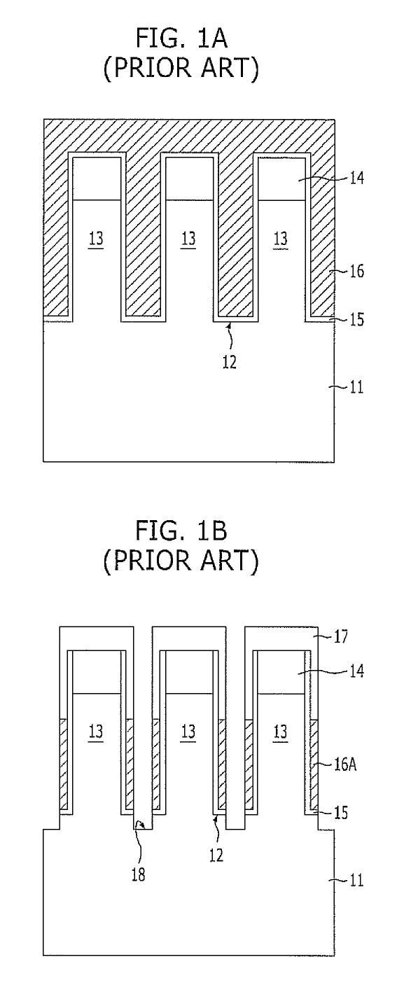

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

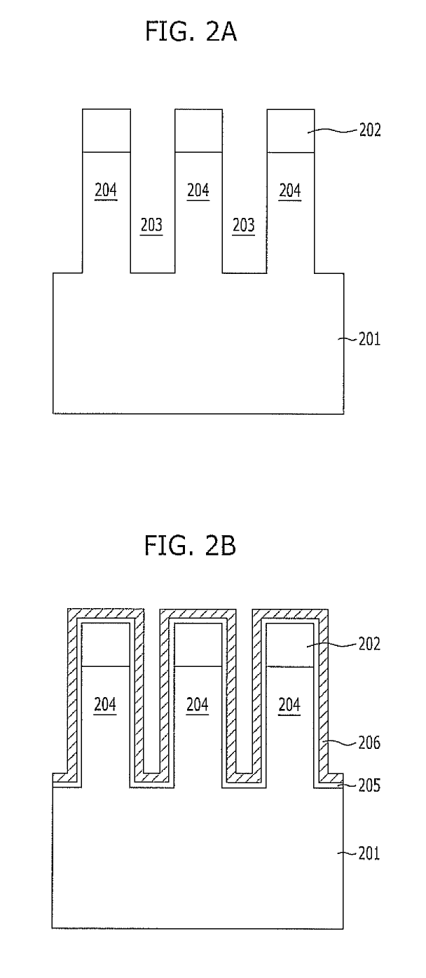

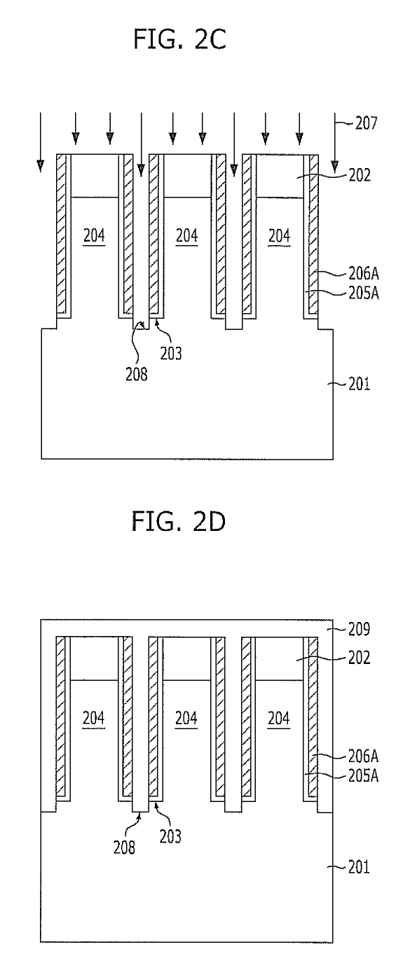

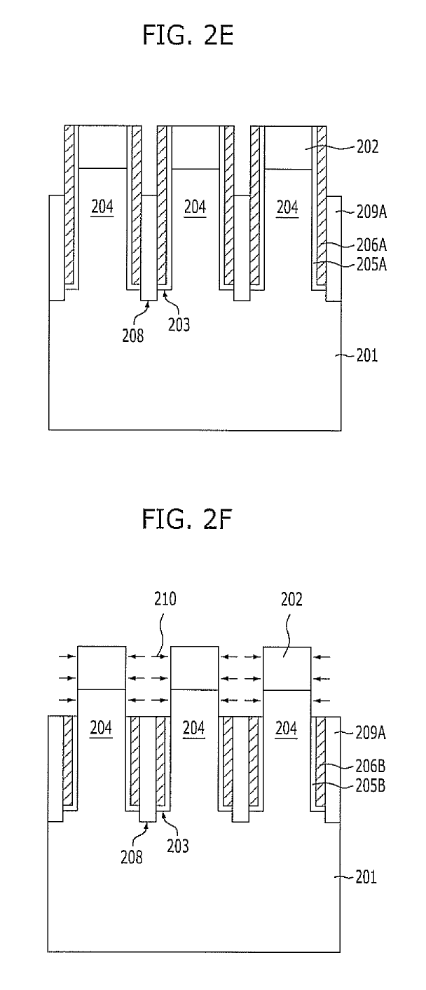

FIGS. 2A to 2F are cross-sectional views illustrating a method for forming vertical gates of a semiconductor device in accordance with a first embodiment of the present invention.

Referring to FIG. 2A, a plurality of pillars 204 are formed over a semiconductor substrate 201 where an assigned structure is already formed. The pillars 204 are formed by etching the semiconductor substrate 201 by using a hard mask layer 202 as an etch barrier. Here, the assigned structure may include buried bit lines. The semiconductor substrate 201 may be a silicon substrate. The hard mask layer 202 may be a dielectric layer, such as an oxide layer and a nitride layer. In the first embodiment, a nitride layer is used as the hard mask layer 202. The pillars 204 are isolated from each other by a plurality of trenches 203 that stretch/extend in any one direction. The pillars 204 are active regions. In particular, the pillars 204 become channels and sources/drains of vertical channel transistors. Each pillar 204 has at least two sidewalls. A fabrication method before the formation of the pillars 204 will be described below.

Referring to FIG. 2B, a conductive layer 206 is formed over the substrate structure including the pillars 204. Here, the conductive layer 206 is formed in the manner of a conformal coating without gap-filling the space between the pillars 204. As a result, the conductive layer 206 having a gap between the pillars 204 is formed. A gate insulation layer 205 is formed before the formation of the conductive layer 206. The conductive layer 206 may be a polysilicon layer, or it may be a metal layer capable of reducing resistance, such as a tungsten layer. Also, the conductive layer 206 may be a metal nitride layer, such as a titanium nitride (TiN) layer. The conductive layer 206 is formed through an Atomic Layer Deposition (ALD) method or a Chemical Vapor Deposition (CVD) method. The gate insulation layer 205 may be formed through a thermal oxidation method or a deposition method. Hereafter, the gate insulation layer 205 formed through the CVD method is described according to an embodiment of the present invention.

Referring to FIG. 2C, a first gate etch process 207 is performed. Here, the first gate etch process 207 is an anisotropic etch process performed in a direction perpendicular to the semiconductor substrate 201. That is, the top surface of the substrate structure may be etched through the etching process more than the side surface thereof. As a result, preliminary gates 206A are formed as the conductive layer 206 is etched. The first gate etch process 207 is a dry etch process, such as an etch method using plasma.

While the first gate etch process 207 is carried out, the gate insulation layer 205 is etched as well as the conductive layer 206 is etched. Also, the surface of the semiconductor substrate 201 is etched by a certain depth (refer to a reference numeral ‘208’). As a result, the preliminary gates 206A are completely isolated. A first gate insulation pattern 205A remains between the preliminary gates 206A and the pillars 204.

Referring to FIG. 2D, an insulation layer 209 is formed over the substrate structure including the preliminary gates 206A. The insulation layer 209 is formed by gap-filling the space between the pillars 204. The insulation layer 209 may be an oxide layer, such as a silicon oxide layer. The insulation layer 209 may be formed of borophosphosilicate glass (BPSG) or Spin-On-Dielectric (SOD) material to gap-fill the space between the pillars 204 without voids.

Referring to FIG. 2E, the insulation layer 209 is recessed. As a result of the recess process, an insulation layer pattern 209A that exposes the upper portion of each preliminary gate 206A is formed. The insulation layer 209 may be recessed through a dry etch process or a wet etch process. The recessed surface of the insulation layer pattern 209A is disposed lower than the upper surface of each pillar 204 by a predetermined depth.

Referring to FIG. 2F, the upper portion of each preliminary gate 206A that is exposed by the insulation layer pattern 209A is selectively removed. This is referred to as a second gate etch process 210. As a result of the second gate etch process 210, vertical gates 206B are formed. The height of the vertical gates 206B is such that an occurrence of a short circuit is prevented during a subsequent Self-Aligned Contact (SAC) process. A second gate insulation pattern 205B remains between the vertical gates 206B and the pillars 204. In short, a portion of the first gate insulation pattern 205A is removed, too, through an isotropic etch process. According to another embodiment of the present invention, the first gate insulation pattern 205A may not be etched.

The second gate etch process 210 is an isotropic etch process. The sides of the vertical gates 206B are protected by the insulation layer pattern 209A during the second gate etch process 210.

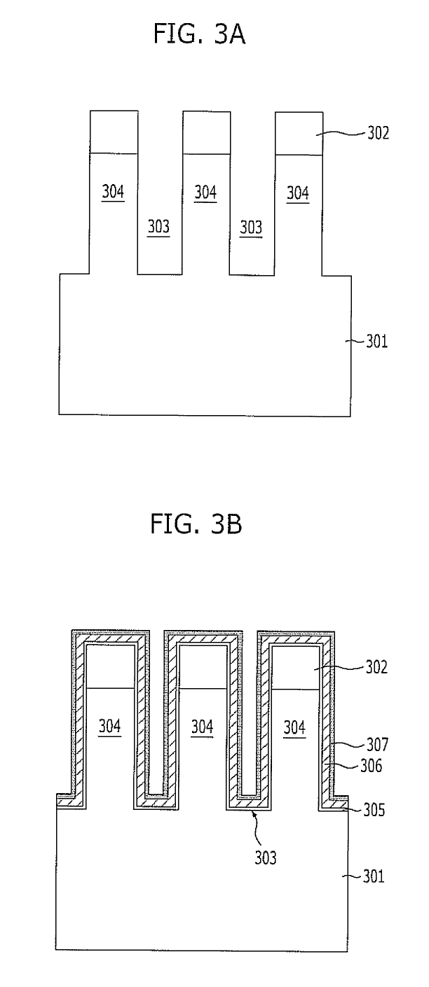

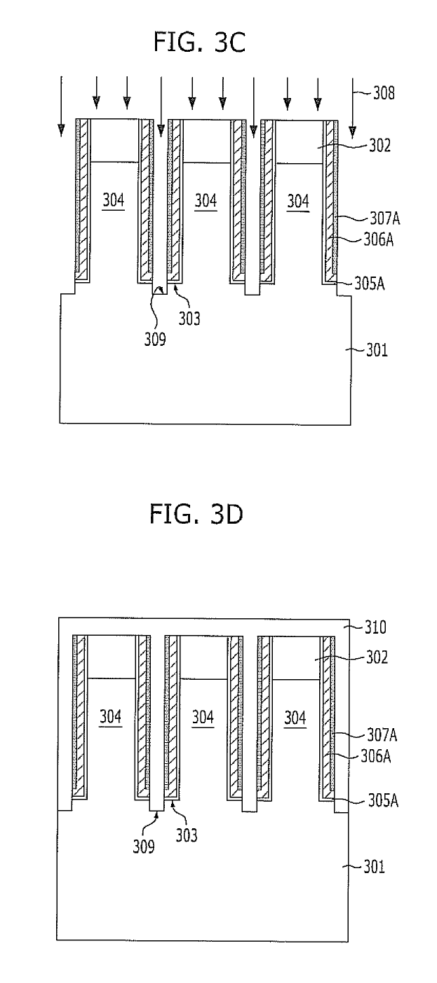

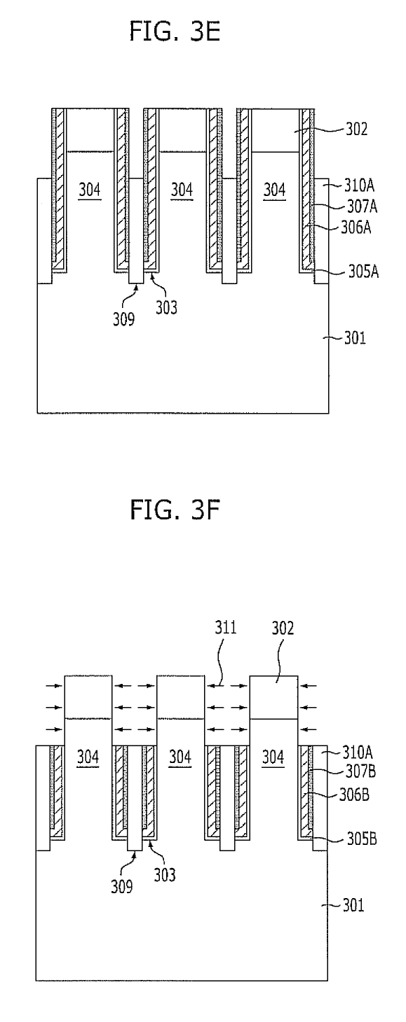

FIGS. 3A to 3F are cross-sectional views illustrating a method for forming vertical gates of a semiconductor device in accordance with a second embodiment of the present invention.

Referring to FIG. 3A, a hard mask layer 302 is formed over a semiconductor substrate 301 where an assigned structure is already formed. Here, the assigned structure may include buried bit lines and bit line contacts. The methods for forming the buried bit lines and the bit line contacts will be described below. The semiconductor substrate 301 may be a silicon substrate. The hard mask layer 302 may be a dielectric layer, such as an oxide layer and a nitride layer. In the second embodiment, a nitride layer is used as the hard mask layer 302.

The semiconductor substrate 301 is etched by a predetermined depth by using the hard mask layer 302 as an etch barrier. As a result, a plurality of pillars 304 that are isolated from each other by trenches 303 are formed. The pillars 304 are active regions. In particular, the pillars 304 become channels and sources/drains of vertical channel transistors. Each pillar 304 has at least two sidewalls.

Referring to FIG. 3B, a conductive layer 306 is formed over the substrate structure including the pillars 304. Here, the conductive layer 306 is formed in the manner of a conformal coating without gap-filling the space between the pillars 304. As a result, the conductive layer 306 having a gap between the pillars 304 is formed. A gate insulation layer 305 is formed before the formation of the conductive layer 306. The conductive layer 306 may be a polysilicon layer, or it may be a metal layer capable of reducing resistance, such as a tungsten layer. Also, the conductive layer 306 may be a metal nitride layer, such as a titanium nitride (TIN) layer. The conductive layer 306 is formed through an Atomic Layer Deposition (ALD) method or a Chemical Vapor Deposition (CVD) method. The gate insulation layer 305 may be formed through a thermal oxidation method or a deposition method. Hereafter, the gate insulation layer 305 formed through the CVD method is described as an embodiment of the present invention.

Subsequently, a protective layer 307 is formed over the conductive layer 306. The protective layer 307 may be a nitride layer, such as a silicon nitride layer. The protective layer 307 serves as a protector against damage caused by plasma during a subsequent gate etch process.

Referring to FIG. 3C, the protective layer 307 is selectively etched. As a result, spacers 307A covering the conductive layer 306 on the sidewalls of the pillars 304 are formed. The spacers 307A are formed through a spacer etch process, which may be an etch-back process.

Subsequently, a first gate etch process 308 is performed. Here, the first gate etch process 308 is an etch process performed in a direction perpendicular to the semiconductor substrate 301. As a result, preliminary gates 306A are formed as the conductive layer 306 is etched. The first gate etch process 308 is a dry etch process, such as an etch method using plasma.

While the first gate etch process 308 is carried out, the gate insulation layer 305 is etched as well as the conductive layer 306 is etched. Also, the surface of the semiconductor substrate 301 is etched by a certain depth (refer to a reference numeral ‘309’). As a result, the preliminary gates 306A are completely isolated. A first gate insulation pattern 305A remains between the preliminary gates 306A and the pillars 304.

During the first gate etch process 308, the spacers 307A, which are a portion of the protective layer 307, protects the sidewalls of the preliminary gates 306A from the damage caused by plasma.

Referring to FIG. 3D, an insulation layer 310 is formed over the substrate structure including the preliminary gates 306A. The insulation layer 310 is formed by gap-filling the space between the pillars 304. The insulation layer 310 may be an oxide layer, such as a silicon oxide layer. The insulation layer 310 may be formed of borophosphosilicate glass (BPSG) or Spin-On-Dielectric (SOD) material to gap-fill the space between the pillars 304 without voids.

Referring to FIG. 3E, the insulation layer 310 is recessed. As a result of the recess process, an insulation layer pattern 310A that exposes the upper portion of each spacer 307A is formed. The insulation layer 310 may be recessed through a dry etch process or a wet etch process. The recessed surface of the insulation layer pattern 310A is disposed lower than the upper surface of each pillar 304 by a predetermined depth.

Referring to FIG. 3F, the upper portion of each spacer 307A that is exposed by the insulation layer pattern 310A is selectively removed. And then, the upper portion of each preliminary gate 306A is selectively removed. This is referred to as a second gate etch process 311. As a result of the second gate etch process 311, vertical gates 306B are formed. The height of the vertical gates 306B is such that an occurrence of a short circuit is prevented during a subsequent Self-Aligned Contact (SAC) process. A second gate insulation pattern 305B remains between the vertical gates 306B and the pillars 304. In short, a portion of the first gate insulation pattern 305A is removed, too, through an isotropic etch process. According to another embodiment of the present invention, the first gate insulation pattern 305A may not be etched. The upper portions of the spacers 307A may be removed with the preliminary gate 306A through the second gate etch process 311 (refer to a reference numeral ‘307B’).

The second gate etch process 311 is an isotropic etch process. The sides of the vertical gate 306B are protected by the insulation layer pattern 310A and the spacers 307B during the second gate etch process 311.

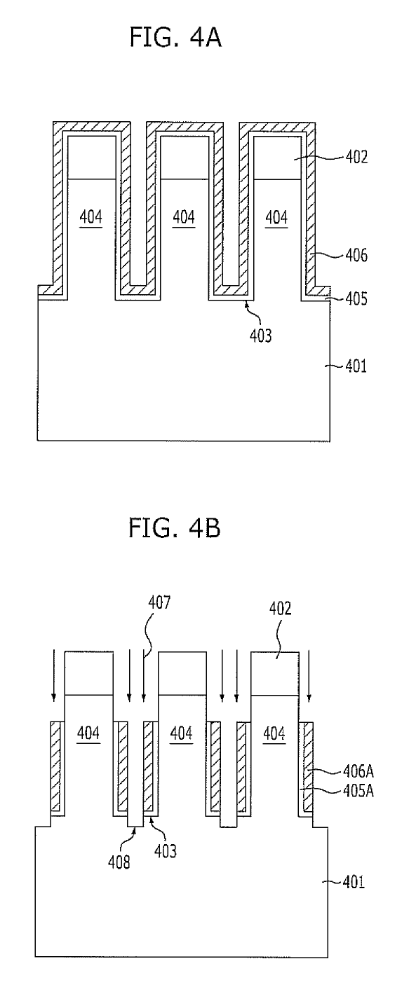

FIGS. 4A and 4B are cross-sectional views illustrating a method for forming vertical gates of a semiconductor device in accordance with a third embodiment of the present invention.

Referring to FIG. 4A, a plurality of pillars 404 are formed over a semiconductor substrate 401 where an assigned structure is already formed. The pillars 404 are formed by etching the semiconductor substrate 401 by using a hard mask layer 402 as an etch barrier. Here, the assigned structure may include buried bit lines. The semiconductor substrate 401 may be a silicon substrate. The hard mask layer 402 may be a dielectric layer, such as an oxide layer and a nitride layer. In the third embodiment, a nitride layer is used as the hard mask layer 402. The pillars 404 are isolated from each other by a plurality of trenches 403 that stretch in any one direction. The pillars 404 are active regions. In particular, the pillars 404 become channels and sources/drains of vertical channel transistors. Each pillar 404 has at least two sidewalk. A fabrication method before the formation of the pillars 404 will be described below.

Subsequently, a conductive layer 406 is formed over the substrate structure including the pillars 404. Here, the conductive layer 406 is formed in the manner of a conformal coating without gap-filling the space between the pillars 404. As a result, the conductive layer 406 having a gap between the pillars 404 is formed. A gate insulation layer 405 is formed before the formation of the conductive layer 406. The conductive layer 406 may be a polysilicon layer, or it may be a metal layer capable of reducing resistance, such as a tungsten layer. Also, the conductive layer 406 may be a metal nitride layer, such as a titanium nitride (TiN) layer. The conductive layer 406 is formed through an Atomic Layer Deposition (ALD) method or a Chemical Vapor Deposition (CVD) method. The gate insulation layer 405 may be formed through a thermal oxidation method or a deposition method. Hereafter, the gate insulation layer 405 formed through the CVD method is described as an embodiment of the present invention.

Referring to FIG. 4B, a gate etch process 407 is performed. Here, the gate etch process 407 is an etch process performed in a direction perpendicular to the semiconductor substrate 401. As a result, vertical gates 406A are formed as the conductive layer 406 is etched. The gate etch process 407 is a dry etch process, such as an etch method using plasma.

While the gate etch process 407 is carried out, the gate insulation layer 405 is etched as well as the conductive layer 406 is etched. Also, the surface of the semiconductor substrate 401 is etched by a certain depth (refer to a reference numeral ‘408’). As a result, the vertical gates 406A are completely isolated. A gate insulation pattern 405A remains between the vertical gates 406A and the pillars 404.

According to the third embodiment of the present invention, differently from the first embodiment, the gate etch process 407 is performed at a time, not the first and second gate etch processes. Therefore, the processes of gap-filling the space between the pillars with an insulation layer, recessing the insulation layer, and performing an isotropic etch process may be omitted.

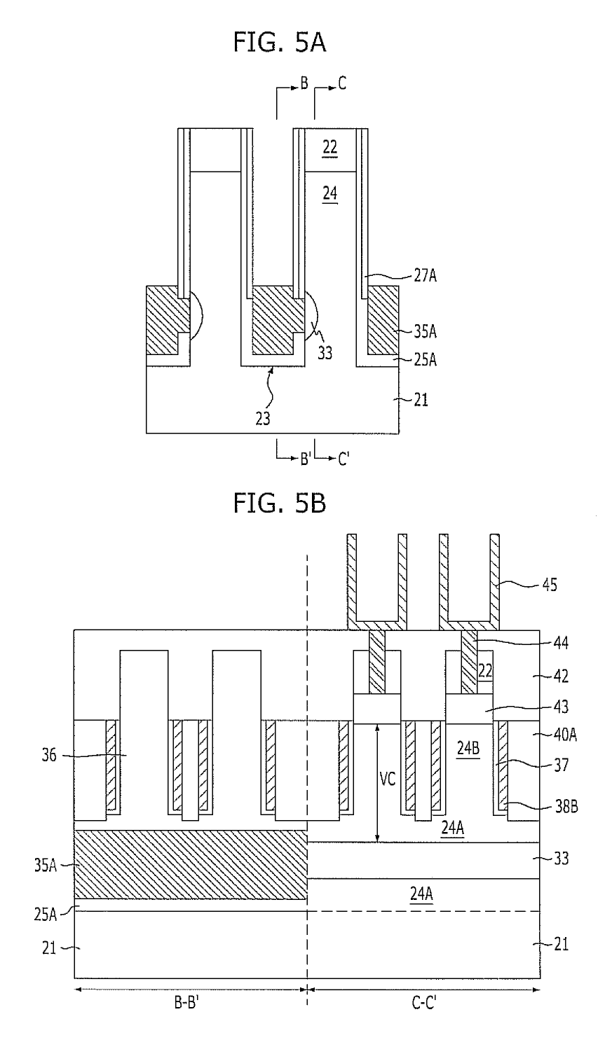

FIGS. 5A and 5B are cross-sectional views illustrating a semiconductor device fabricated through a vertical gate forming method according to an embodiment of the present invention. FIG. 5A is a cross-sectional view of the semiconductor device wherein buried bit lines are formed before the formation of vertical gates, and FIG. 5B is a cross-sectional view of the semiconductor device wherein vertical gates are formed. FIG. 5B shows the cross sections taken along a B-B′ line and a C-C′ line.

Referring to FIG. 5A, bodies 24 that are isolated from each other by the trenches 23 are formed over a semiconductor substrate 21. An insulation layer is formed on the sidewalls of the bodies 24 and the surface of the trenches 23. The insulation layer includes a first liner layer pattern 25A and a second liner layer pattern 27A. The insulation layer includes openings, and a first junction 33 is formed on any one sidewall of a body 24 that is exposed through the opening. Subsequently, buried bit lines 35A are formed to fill a portion of the inside of each trench 23. The buried bit lines 35A are coupled with the first junctions 33.

Referring to FIG. 5B, each body 24 is divided into an active body 24A and an active pillar 24B. A plurality of active pillars 24B are formed over the active body 24A by etching the body 24. A first inter-layer dielectric layer 36 is formed between the active pillars 24B of different bodies 24. Vertical gates 38B are formed on the sidewalls of the active pillars 24B with a gate insulation layer 37 interposed between them. A second inter-layer dielectric layer 40A is formed between the vertical gates 38B. A third inter-layer dielectric layer 42 is formed over the second inter-layer dielectric layer 40A. Subsequently, storage node contact plugs 44 are coupled with the upper portions of the active pillars 24B by passing through the third inter-layer dielectric layer 42 and a hard mask layer 22. Second junctions 43 are formed in the upper portion of the active pillars 24B, and the second junctions 43 are coupled with the storage node contact plugs 44. Vertical channels VC are formed by the vertical gates 38B between the first junction 33 and the second junctions 43. Subsequently, storage nodes 45 of a capacitor are formed over the storage node contact plugs 44.

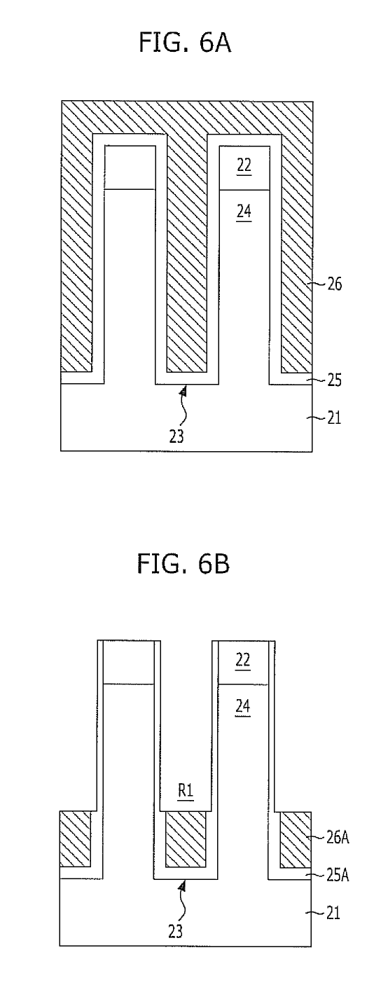

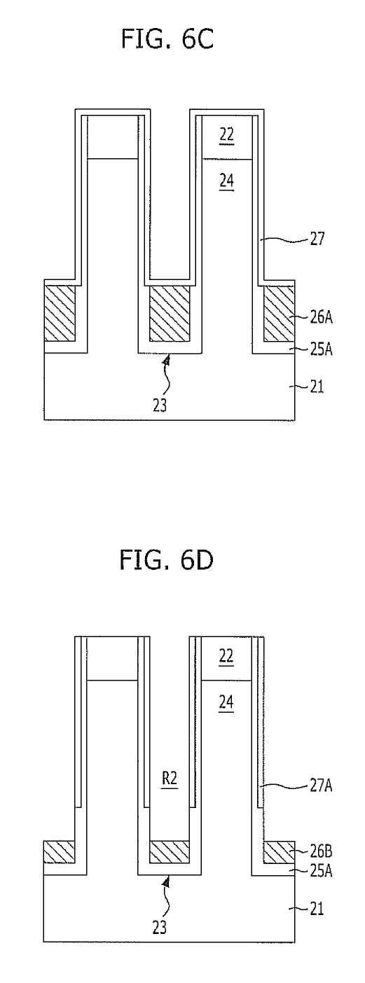

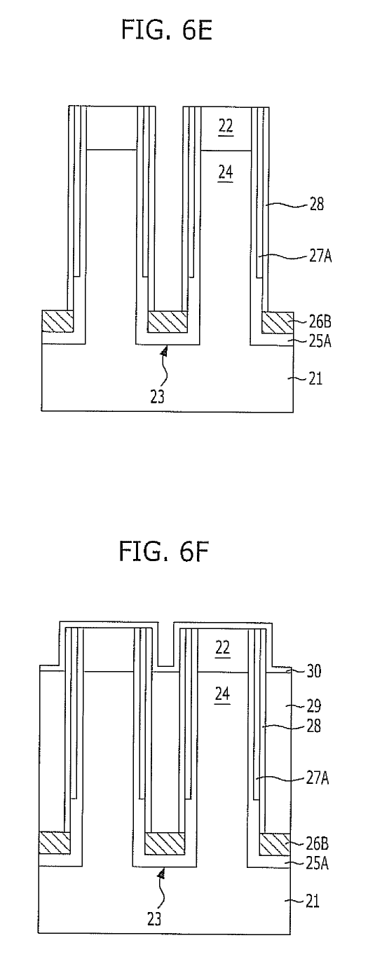

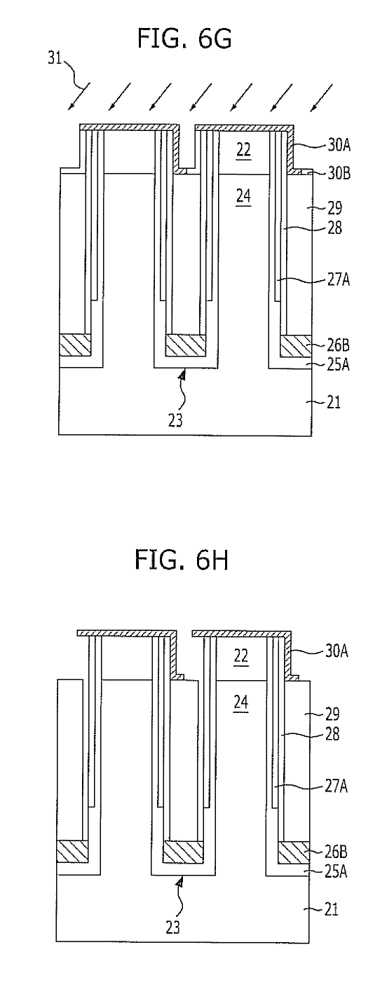

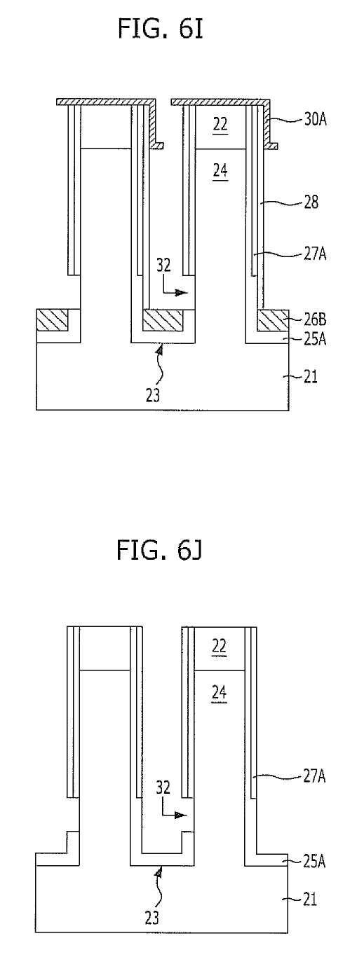

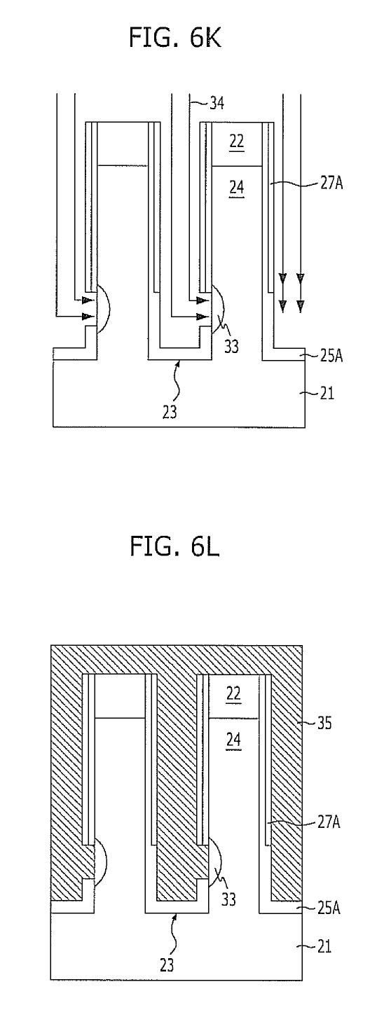

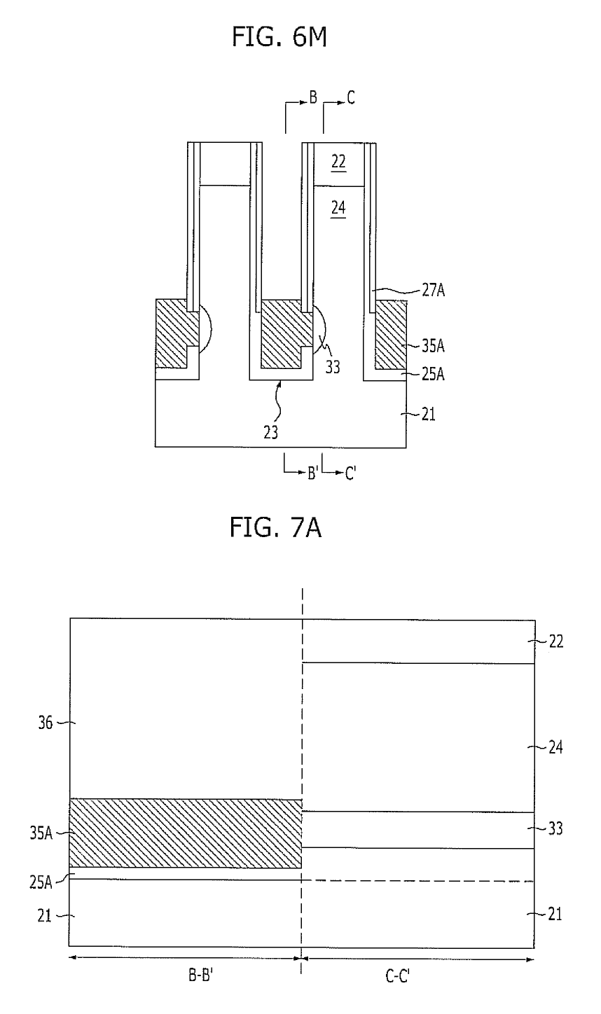

FIGS. 6A to 6M are cross-sectional views illustrating a vertical gate forming method until the formation of buried bit lines (i.e., before the formation of vertical gates), which is shown in FIG. 5A.

Referring to FIG. 6A, a hard mask layer 22 is formed over a semiconductor substrate 21. The semiconductor substrate 21 may be a silicon substrate. The hard mask layer 22 may be a nitride layer. Also, the hard mask layer 22 may be of a multi-layer structure including an oxide layer and a nitride layer.

For example, the hard mask layer 22 may be formed by sequentially stacking a hard mask nitride layer and a hard mask oxide layer. Also, the hard mask layer 22 may be formed by sequentially stacking a hard mask nitride layer, a hard mask oxide layer, a hard mask silicon oxynitride (SION) layer, and a hard mask carbon layer. When the hard mask layer 22 includes a hard mask nitride layer, a pad oxide layer may be additionally formed between the semiconductor substrate 21 and the hard mask layer 22. The hard mask layer 22 is formed using a photoresist layer patter, which is not illustrated in the drawings.

Subsequently, a trench etch process is performed using the hard mask layer 22 as an etch barrier. For example, bodies 24 are formed by etching the semiconductor substrate 21 by a predetermined depth by using the hard mask Layer 22 as an etch barrier. The bodies 24 are isolated from each other by trenches 23. The bodies 24 include active regions where transistors are formed. Each of the bodies 24 has two sidewalls. A trench etch process may be an anisotropic etch process. When the semiconductor substrate 21 is a silicon substrate, the anisotropic etch process may be a plasma dry etch process that uses chlorine (Cl₂) gas, hydrogen bromide (HBr) gas, or a mixed gas thereof. The multiple bodies 24 are formed over the semiconductor substrate 21 by forming the trenches 23.

A first liner layer 25 is formed as an insulation layer. The first liner layer 25 may be an oxide layer, such as a silicon oxide layer.

A sacrificial layer 26 is formed over the first liner layer 25 to gap-fill the trenches 23 between the bodies 24. The sacrificial layer 26 includes undoped polysilicon or amorphous silicon.

Referring to FIG. 6B, the sacrificial layer 26 is planarized until the surface of the hard mask layer 22 is exposed. The planarization of the sacrificial layer 26 may be performed through a Chemical Mechanical Polishing (CMP) process. Subsequently, an etch-back process is performed. As a result of the etch-back process, a sacrificial layer pattern 26A that provides a first recess R1 is formed. During the CMP process, the first liner layer 25 over the hard mask layer 22 may be polished. As a result, a first liner layer pattern 25A covering both sidewalls of the hard mask layer 22 and the body 24 is formed. The first liner layer pattern 25A covers the bottom of each trench 23 as well.

Subsequently, the first liner layer pattern 25A goes through a slimming process through a wet etch process. Here, the first liner layer pattern 25A may remain to have a predetermined thickness on the sidewalls of the bodies 24 by controlling the time for performing the wet etch process.

Referring to FIG. 6C, a second liner layer 27 is formed as an insulation layer over the substrate structure including the sacrificial layer pattern 26A. The second liner layer 27 may be a nitride layer, such as a silicon nitride layer. The second liner layer 27 is formed to have the same thickness as the thickness of the slimmed first liner layer pattern 25A.

Referring to FIG. 6D, the second liner layer 27 is selectively etched. As a result, a second liner layer pattern 27A is formed in the slimmed area of the first liner layer pattern 25A. The second liner layer pattern 27A may be formed through an etch-back process, and as a result, the second liner layer pattern 27A comes to have a shape of a spacer.

Subsequently, the sacrificial layer pattern 26A is recessed by a predetermined depth by using the second liner layer pattern 27A as an etch barrier. As a result, a second recess R2 that exposes the surface of a portion of the first liner layer pattern 25A is formed. The recessed sacrificial layer pattern is denoted with a reference numeral ‘26B’. When the sacrificial layer pattern 26A includes polysilicon, the recess process is performed through an etch-back process.

Referring to FIG. 6E, a metal nitride layer is formed over the substrate structure including the second recess R2 in the manner of a conformal coating. Subsequently, a sacrificial spacer 28 is formed through a spacer etch process. The sacrificial spacer 28 is formed on both sidewalls of each body 24. The sacrificial spacer 28 may be a titanium nitride (TIN) layer.

Referring to FIG. 6F, a gap-fill layer is formed to gap-fill the second recess R2 where the sacrificial spacer 28 is formed. The gap-fill layer may be an oxide layer. The gap-fill layer may be a Spin-On Dielectric (SOD) layer.

Subsequently, after the gap-fill layer is formed, an etch-back process is performed. As a result, a recessed gap-fill layer 29 is formed.

A third liner layer 30 is formed over the substrate structure including the recessed gap-fill layer 29. The third liner layer 30 includes undoped polysilicon.

Referring to FIG. 6G, a tilt ion implantation process 31 is performed.

The tilt ion implantation process 31 is performed to implant the ions of a dopant at a predetermined angle. The dopant is implanted into a portion of the third liner layer 30.

The tilt ion implantation process 31 is performed at a predetermined angle, which ranges from approximately 5° to approximately 30°. A portion of the third liner layer 30 is shadowed from the ion beam by the hard mask layer 22. Therefore, a portion of the third liner layer 30 is doped while the other portion remains undoped. For example, the dopant ion-implanted is a P-type dopant, e.g., boron (B), and a dopant source used for ion-implanting boron is boron fluoride (BF₂). As a result, a portion of the third liner layer 30 remains undoped. The undoped portion is a portion adjacent to the left side of the hard mask layer 22.

A portion of the third liner layer 30 formed on the upper surface of the hard mask layer 22 and a portion of the third liner layer 30 formed adjacent to the right side of the hard mask layer 22 become a doped third liner layer 30A. The portion of the third liner layer 30 that is not doped with the dopant becomes an undoped third liner layer 30B.

Referring to FIG. 6H, the undoped third liner layer 30B is removed. Here, the polysilicon used as the third liner layer has different etch rates depending on whether it is doped with the dopant or not. In particular, undoped polysilicon into which the dopant is not implanted has a high etch rate. Therefore, the undoped polysilicon is selectively removed by using a chemical having a high selectivity and thus capable of wet-etching the undoped polysilicon other than the doped polysilicon. The undoped third liner layer 30B is removed through a wet etch process or a wet cleaning process.

After the undoped third liner layer 30B is removed, the doped third liner layer 30A remains.

Subsequently, one of the sacrificial spacers 28 in each trench 23 is removed. As a result, a gap (not denoted with a reference numeral) is formed between the gap-fill layer 29 and the second liner layer pattern 27A. The sacrificial spacer 28 is removed through a wet etch process. As a result, one sacrificial spacer 28 remains in each trench 23.

Referring to FIG. 6I, a cleaning process is performed to expose a portion of a sidewall of each body 24.

The cleaning process may be a wet cleaning process. The wet cleaning process is performed using hydrogen fluoride (HF) or a buffered oxide etchant (BOE). Through the wet cleaning process, the first liner layer pattern 25A may be selectively etched without damaging the sacrificial layer pattern 26B, the sacrificial spacers 28, and the second liner layer pattern 27A.

As described above, the hard mask layer 22, the first liner layer pattern 25A, the second liner layer pattern 27A, the sacrificial layer pattern 26B, and the sacrificial spacers 28 are collectively referred to as an ‘insulation layer’. Therefore, the insulation layer provides an opening 32 that exposes a portion of any one sidewall of each body 24.

Referring to FIG. 6J, the doped third liner layer 30A is removed. Here, since both of the doped third liner layer 30A and the sacrificial layer pattern 26B are formed of polysilicon, they are removed simultaneously.

Subsequently, the sacrificial spacers 28 are removed.

Referring to FIG. 6K, a first junction 33 is formed on the sidewall of each body 24 where the opening 32 is disposed. The first junction 33 may be formed through a tilt ion implantation process or a plasma doping process. Hereafter, it is described as an example that the first junction 33 is formed through the plasma doping process 34. The impurity doped to form the first junction 33 has a doping concentration of approximately 1×10²⁰ atoms/cm³ or higher. The first junction 33 is doped with phosphorus (P) or arsenic (As). As a result, the first junction 33 becomes an N-type junction. Through the plasma doping process 34, the depth (side surface diffusion depth) of the first junction 33 may be controlled to be shallow. Also, the concentration of the dopant is controlled easily. The first junction 33 becomes a source or drain of a vertical channel transistor.

Referring to FIG. 6L, a first conductive layer 35 is formed over the substrate structure including the first junction 33. The first conductive layer 35 gap-fills the space between the bodies 24. The first conductive layer 35 is used as buried bit lines, and it is formed of a material having a low resistance. For example, the first conductive layer 35 may be a metal layer or a metal nitride layer. The first conductive layer 35 may be a titanium nitride (TiN) layer.

Referring to FIG. 6M, a planarization process and an etch-back process are sequentially performed on the first conductive layer 35. As a result, a first conductive layer pattern 35A remains in each trench 23. The planarization process is performed until the surface of the hard mask layer 22 is exposed. For example, the planarization process is performed through a CMP process. The first conductive layer pattern 35A is formed as buried bit lines through the etch-back process. Hereafter, the first conductive layer pattern 35A is referred to as buried bit lines 35A. Since the buried bit lines 35A are formed of a metal layer or a metal nitride layer, the buried bit lines 35A may have a low resistance.

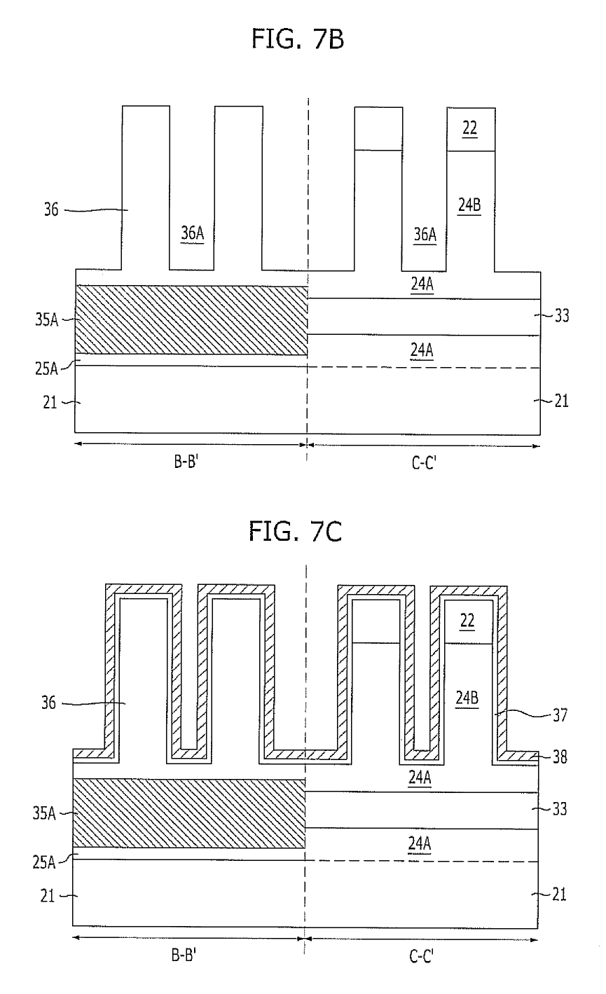

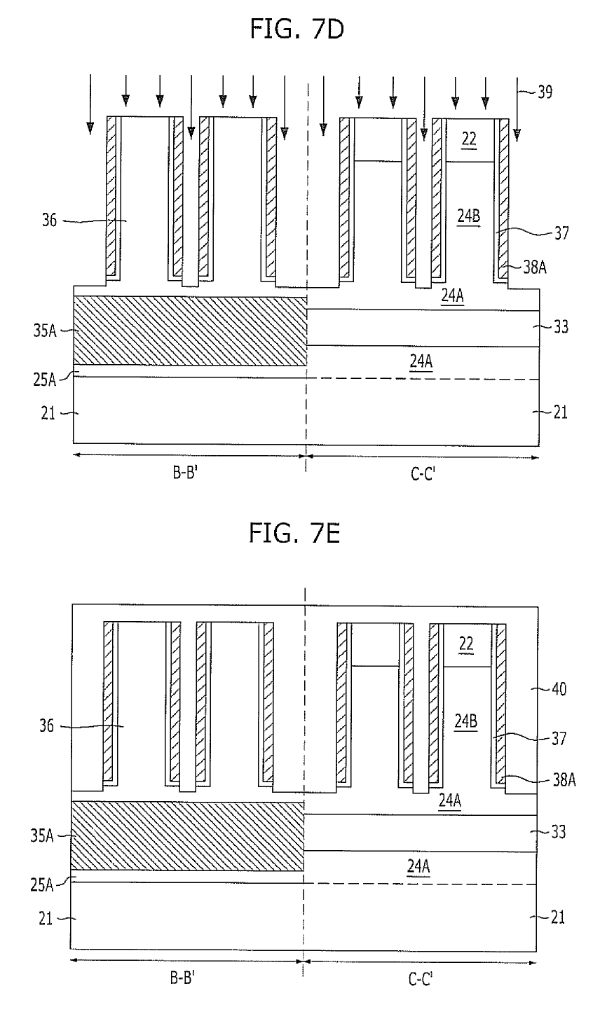

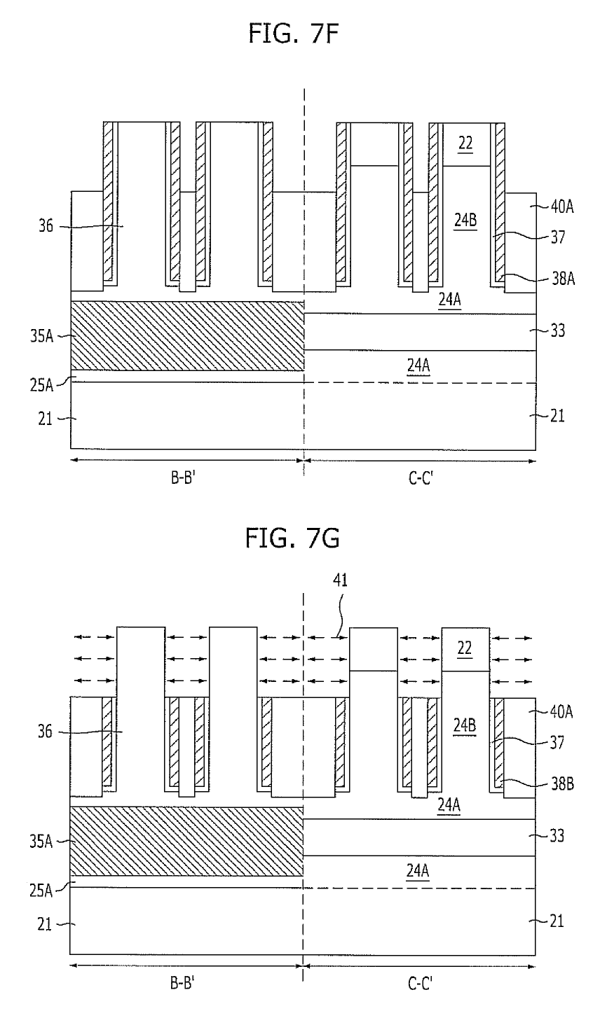

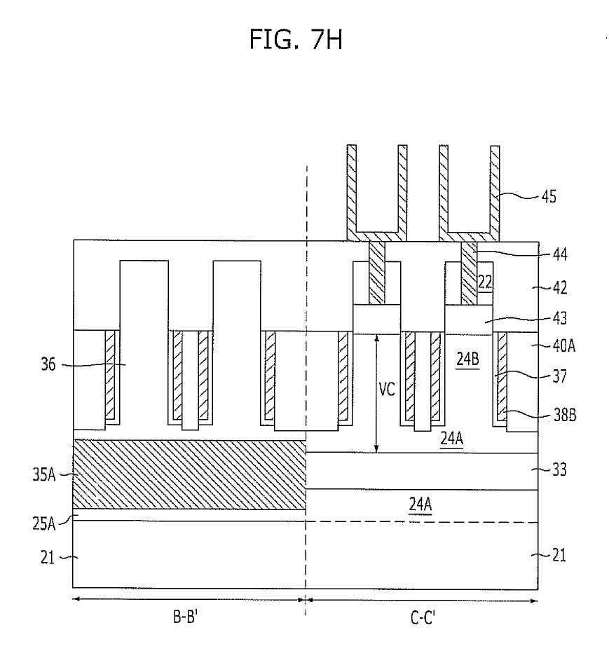

FIGS. 7A to 7H are cross-sectional views illustrating a vertical gate forming method after the formation of buried bit lines, which is shown in FIG. 5B. Hereafter, for the purpose of description, FIGS. 7A to 7H show the cross-sections taken along the line B-B′ and the line C-C′ shown in FIG. 6M together.

Referring to FIG. 7A, a first inter-layer dielectric layer 36 is formed over the substrate structure including the buried bit lines 35A. The first inter-layer dielectric layer 36 gap-fills space over the buried bit lines 35A. The first inter-layer dielectric layer 36 may be an oxide layer, such as a BPSG layer.

Subsequently, the first inter-layer dielectric layer 36 is planarized until the surface of the hard mask layer 22 is exposed. The planarization is performed through a CMP process.

Subsequent processes may be performed according to one among the first to third embodiments of the present invention.

Referring to FIG. 7B, the upper portions of the first inter-layer dielectric layer 36 and the bodies 24 are etched. The first inter-layer dielectric layer 36 and the bodies 24 are etched using a photoresist layer pattern, which is not illustrated in the drawing. The photoresist layer pattern is a line/space pattern stretching in a direction crossing the buried bit lines 35A. As a result, the buried bit lines 35A and the photoresist pattern cross with each other. The first inter-layer dielectric layer 36 is etched by a predetermined depth by using the photoresist pattern as an etch barrier. When the first inter-layer dielectric layer 36 is etched, the hard mask layer 22 and the bodies 24 are etched by a predetermined depth.

As a result, each body 24 is divided into an active body 24A and an active pillar 24B. A plurality of active pillars 24B are formed on the active body 24A. In short, a plurality of active pillars 24B are formed over one active body 24A, and the active pillars 24B are isolated from each other by word line trenches 36A. For reference, the bodies 24, i.e., the active bodies 24A, are separated by the trenches 23. The active bodies 24A and the active pillars 24B constitute active regions. The active bodies 24A have the first junctions 33 formed therein and have a shape of lines stretching in the same direction as the buried bit lines 35A. The active pillars 24B are pillars stretching vertically from the active bodies 24A. The active pillars 24B are formed on the basis of a memory cell. The remaining first inter-layer dielectric layer 36 serves as an isolation layer between the buried bit lines 35A and the vertical gates.

Referring to FIG. 7C, a second conductive layer 38 is formed over the substrate structure including the active pillars 24B. Here, the second conductive layer 38 is formed in the manner of a conformal coating instead of gap-filling the space between the active pillars 24B. As a result, while a gap is secured between the active pillars 24B, the second conductive layer 38 is formed. Before the second conductive layer 38 is formed, a gate insulation layer 37 is formed. The second conductive layer 38 may be a polysilicon layer, or the second conductive layer 38 may be a metal layer, such as a tungsten layer, to decrease resistance. Also, the second conductive layer 38 may be a metal nitride layer, such as a titanium nitride (TiN) layer. The second conductive layer 38 is formed through an Atomic Layer Deposition (ALD) or a Chemical Vapor Deposition (CVD) method. The gate insulation layer 37 may be formed through a thermal oxidation process or a deposition process. Hereafter, the gate insulation layer 37 formed through the CVD process is described according to an embodiment of the present invention.

Referring to FIG. 7D, a first gate etch process 39 is performed. Here, the first gate etch process 39 is an etch process performed in a direction perpendicular to the semiconductor substrate 21. As a result, the second conductive layer 38 is etched to form preliminary gates 38A. The first gate etch process 39 is a dry etch process, such as a plasma dry etch process.

During the first gate etch process 39, the gate insulation layer 37 is etched as well as the second conductive layer 38. Also, the surface of the semiconductor substrate 21 is etched by a certain depth. As a result the preliminary gates 38A are completely isolated. A gate insulation layer remains between the preliminary gates 38A and the active pillars 24B.

Referring to FIG. 7E, a second inter-layer dielectric layer 40 is formed over the substrate structure including the preliminary gates 38A. The second inter-layer dielectric layer 40 is formed by gap-filling the space between the active pillars 24B. The second inter-layer dielectric layer 40 may be an oxide layer, such as a silicon oxide layer. The second inter-layer dielectric layer 40 may be formed of borophosphosilicate glass (BPSG) or Spin-On-Dielectric (SOD) material to gap-fill the space between the active pillars 24B without voids.

Referring to FIG. 7F, the second inter-layer dielectric layer 40 is recessed. As a result of the recess process, a second inter-layer dielectric layer pattern 40A that exposes the upper portion of each preliminary gate 38A is formed. The second inter-layer dielectric layer 40 may be recessed through a dry etch process or a wet etch process. The recessed surface of the second inter-layer dielectric layer pattern 40A is disposed lower than the upper surface of each active pillar 24B by a predetermined depth.

Referring to FIG. 7G, the upper portion of each preliminary gate 38A that is exposed by the second inter-layer dielectric layer pattern 40A is selectively removed. This is referred to as a second gate etch process 41. As a result of the second gate etch process 41, vertical gates 38B are formed. The height of the vertical gates 38B is such that an occurrence of a short circuit is prevented during a subsequent Self-Aligned Contact (SAC) process. The gate insulation layer 37 remains between the vertical gates 38B and the active pillars 24B. In short, a portion of the gate insulation layer 37 is removed, too, through an isotropic etch process. According to another embodiment of the present invention, the gate insulation layer 37 may not be etched.

The second gate etch process 41 may be an isotropic etch process. During the second gate etch process 41, the sides of each vertical gate 38B are protected by the second inter-layer dielectric layer pattern 40A.

Referring to FIG. 7H, a third inter-layer dielectric layer 42 is formed over the substrate structure including the vertical gates 38B.

The upper surfaces of the active pillars 24B are exposed by performing a storage node contact etch process. Subsequently, storage node contact plugs (SNC) 44 are formed. Before the storage node contact plugs 44 are formed, second junctions 43 each of which serves as another junction, that is, a drain, may be formed through an ion implantation process. As a result, the second junction 43, the first junction 33, and the vertical gate 38B form a vertical channel transistor. A vertical channel VC is formed by the vertical gate 38B between the second junction 43 and the first junction 33. The first junction 33 becomes a source of the vertical channel transistor.

A storage node 45 of a capacitor is formed over the storage node contact plug 44. The storage node 45 may be of a cylindrical shape. According to another embodiment of the present invention, the storage node 45 may be formed in a pillar shape or a concave shape. Subsequently, a dielectric layer and an upper electrode (not shown) are formed.

According to an embodiment of the present invention, vertical gates may be easily isolated by using one-directional etch process and an isotropic etch process instead of using a photoresist layer patter, and the loss of a semiconductor substrate may be controlled uniformly.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a plurality of pillars by etching a semiconductor substrate;
forming a conductive layer over a semiconductor substrate structure including the pillars;
forming preliminary gates on sidewalls of each pillar by performing a first etch process on the conductive layer; and
forming vertical gates by performing a second etch process on upper portions of the preliminary gates.

2. The method of claim 1, wherein the forming of the vertical gates by performing the second etch process on the upper portions of the preliminary gates comprises:
forming an insulation layer over the preliminary gates to gap-fill space between the pillars;
recessing the insulation layer; and
removing the upper portions of the preliminary gates that are exposed by the recessed insulation layer.

3. The method of claim 2, wherein the upper portions of the preliminary gates are removed through an isotropic etch process.

4. The method of claim 2, wherein the insulation layer is recessed through a wet etch process.

5. The method of claim 1, wherein the first etch process is performed through an etch process performed in a direction perpendicular to the semiconductor substrate, and the second etch process is performed through an isotropic etch process.

6. The method of claim 1, wherein in the forming of the conductive layer,
the conductive layer comprises polysilicon or metal.

7. The method of claim 1, further comprising, after the forming of the conductive layer:
forming a protective layer over a semiconductor substrate structure including the conductive layer; and
performing a spacer etch process on the protective layer.

8. The method of claim 7, wherein in the forming of the protective layer,
the protective layer comprises a nitride layer.

9. The method of claim 1, wherein in the forming of the conductive layer,
the conductive layer is formed as a conformal coating layer.

10. A method of fabricating a semiconductor device, comprising:
forming a plurality of pillars by etching a semiconductor substrate;
forming a conductive layer over a semiconductor substrate structure including the pillars; and
forming vertical gates by etching the conductive layer through an etch process performed in a direction perpendicular to the semiconductor substrate.

11. The method of claim 10, wherein the etch process comprises an etch process which etches a top surface of a semiconductor substrate structure including the conductive layer.

12. A method of fabricating a semiconductor device, comprising:
forming a plurality of bodies that are isolated from each other by a plurality of first trenches by etching a semiconductor substrate;
forming buried bit lines that are coupled with the respective bodies at a portion of one sidewall thereof by partially filling the first trenches;
forming a plurality of pillars that are isolated from each other by a plurality of second trenches crossing the first trenches by etching the upper portion of each body;
forming a conductive layer over a semiconductor substrate structure including the pillars;
forming preliminary gates on sidewalls of each pillar by performing a first etch process on the conductive layer; and
forming vertical gates by performing a second etch process on the upper portions of the preliminary gates.

13. The method of claim 12, further comprising:
forming a capacitor including a storage node that is coupled with the upper portion of each pillar.

14. The method of claim 12, wherein the forming of the vertical gates by performing the second etch process on the upper portions of the preliminary gates comprises:
forming an insulation layer over the preliminary gates to gap-fill space between the pillars;
recessing the insulation layer; and
removing the upper portions of the preliminary gates that are exposed by the recessed insulation layer.

15. The method of claim 14, wherein the upper portions of the preliminary gates are removed through an isotropic etch process.

16. The method of claim 14, wherein the insulation layer is recessed through a wet etch process.

17. The method of claim 12, wherein the first etch process is performed through an etch process that is performed in a direction perpendicular to the semiconductor substrate, and the second etch process is performed through an isotropic etch process.

18. The method of claim 12, wherein in the forming of the conductive layer,
the conductive layer comprises polysilicon or metal.
